(19) United States
(12) Patent Application Publication
(10) Pub. No.: US 2015/0273705 A1
(43) Pub. Date: Oct. 1, 2015

(54) COATED SNAP CUTTER BLADE AND METHOD OF MAKING SAME

(71) Applicant: 3M INNOVATIVE PROPERTIES COMPANY, Saint Paul, MN (US)

(72) Inventor: Michitomo Kugimiya, Kanagawa (JP)

(21) Appl. No.: 14/441,639

(22) PCT Filed: Nov. 8, 2013
(86) PCT No.: PCT/US13/69179

§ 371 Date: May 8, 2015

(30) Foreign Application Priority Data
Nov. 9, 2012 (JP) 2012-247535

(51) Int. Cl. B26B 9/00; C23C 16/34

(52) U.S. Cl. CPC B26B 9/00; C23C 16/34

(57) ABSTRACT

A snap cutter blade 10 comprising a core and an enhancement coating thereon wherein wherein the enhancement coating at least covers both the first side and the second side of the cutting tip 11a. Also a method for making such snap cutter blades.

### FIELD

The present invention relates to “snap” or “snap-off” type cutter blades with edge enhancement coatings and methods for making such blades.

### BACKGROUND

Utility knives in many forms are well known. Use of segmented blades from which segments are successively snapped off, sometimes referred to as “snap” or “snap-off” blades, to successively present sharp points or tips in place of worn segments are well known. Introduced by Olfa Corporation of Japen with illustrative examples disclosed in U.S. Pat. No. 4,063,356 (Hepworth) and U.S. Pat. No. 4,170,062 (Machida).

Segmented or snap blades are conventionally made from stainless steel in configurations having standard length, thickness, snap off line ditch, and width.

Though stainless steel blades in other applications, e.g., scissors, conventional knife blades, etc., are typically made with edge enhancement coatings, e.g., a titanium coating, to impart high cutting ability, abrasion resistance, and improved edge maintenance. For example, a coating for a blade surface is described in Japanese Patent Laid-Open No. 10-146702. That reference discloses a coating for a surface blade forming the surface hardening layer.

Prior to this invention, snap blades with such coatings have not been acceptable for several performance reasons. Typically, the coatings are subject to chipping during use and when segments are snapped off. In many instances, the coatings may interfere with the desired ease with which segments may be snapped off. Also the process(s) employed to apply the coatings to the blade may degrade the base material in such a way as to interfere with the blade's performance, e.g., result in softening of the base material such that a sharp edge is not maintained during use.

The need exists for improved snap cutter blades with enhancement coatings and methods for making them.

### SUMMARY OF THE INVENTION

The present invention provides improved snap cutter blades with edge enhancement coatings and methods for making such blades.

In brief summary, snap cutter blades of the invention comprise a core and an enhancement coating thereon wherein:
(a) the blade is an elongate body having two major surfaces connected by a first edge and a second edges and a first end and a second end, the first and second edges each extending from the first end to the second end;
(b) at least one edge of the blade is a cutting edge having a cutting tip having two sides, a first side corresponding to the first major surface of the blade and a second side corresponding to the second major surface of the blade; and
(c) the blade has two or more weakened lines of separation, the weakened lines of separation being parallel to one another and being located in longitudinal intervals, defining segments of the blade;
   wherein the enhancement coating covers at least both the first side and the second side of the cutting tip, and the ratio of the depth of the weakened line of separation to the cutter blade thickness is from about 0.10 to about 0.60.

Briefly summarizing, methods for making snap cutter blades of the invention comprise:
(a) providing a blade core wherein:
   (1) the blade core is an elongate body having two major surfaces connected by a first edge and a second edges and a first end and a second end, the first and second edges each extending from the first end to the second end;
   (2) at least one edge of the blade core is a cutting edge having a cutting tip having two sides, a first side corresponding to the first major surface of the blade core and a second side corresponding to the second major surface of the blade core; and
   (3) the blade core has one or more weakened lines of separation, the weakened lines of separation being parallel to one another and being located in longitudinal intervals, defining segments of the blade core; and
(b) forming an edge enhancement coating thereon by applying a coating composition to both sides of the cutting tip;
   to yield a snap cutter blade.

Snap cutter blades of the invention provide superior performance, including superior flexibility, wear resistance, corrosion resistance, resistance to chipping, and hardness. In addition, blade segments can be snapped-off easily to present fresh cutting edges and cutting tips.

### BRIEF DESCRIPTION OF THE DRAWINGS

The invention is further explained with reference to the drawing wherein:

FIG. 1 is a plan view of an illustrative embodiment of a cutter blade of the invention;

FIG. 2 is a plan view of another illustrative embodiment of a cutter blade of the invention;

FIG. 3(a) is a cross-sectional view of the cutter blade describing the depth of a blade snap-off line;

FIG. 3(b) is a drawing of the cutter blade seen from a longitudinal direction describing a cutting edge angle;

FIG. 4(a) is a perspective view showing the measurements of the cutter blade in the blade folding power test;

FIG. 4(b) is a top view showing the measuring point of the cutter blade in the blade folding power test;

FIG. 5(a) is a drawing showing the measurements of the cutter blade in the flexibility test;

FIG. 5(b) is a drawing describing the allowable bending angle of the cutter blade;

FIG. 6(a) is a drawing showing a condition where the second blade snap-off line from the point was exposed from the holder tip in the blade breakage test;

FIG. 6(b) is a drawing showing where the blade is held with pliers to stretch over the first blade snap-off line from the tip in the blade breakage test;

FIG. 7(a) is a drawing showing where blade is broken off at the second snap-off line from the point in the blade breakage test;

FIG. 7(b) is a drawing showing an example of when the blade is broken off at a place other than the blade snap-off line;

FIG. 8(a) is a drawing showing when there was no change in the shape of the point in the chipping blade test;

FIG. 8(b) is a drawing showing an example of when there was a change in the form of the point; and

FIG. 9 is a graph showing the relation between the number of cuts and the depth of cuts in the embodiment and the comparative example.

These figures are not to scale and are intended to be merely illustrative and non-limiting.

### DETAILED DESCRIPTION OF ILLUSTRATIVE EMBODIMENTS

Hereinafter, suitable embodiments of the present invention will be described in detail with reference to the drawings. In the drawings, the following reference characters are used:

| Reference Character | Item or Feature |
|---|---|
| 9 | Body portion of blade |
| 10, 20 | Cutter blade |
| 10a | Surface |
| 11, 21 | Cutting edge portion of blade |
| 11a, 21a | Cutting tip |
| 11b, 11c | Cutting tip sides |
| 12, 22 | Through-hole |
| 13, 23 | Snap-off or weakened separation line |
| 13a | Bottom |
| 14 | Edge enhancement coating |
| 30 | Vice |
| α | Cutting edge angle |
| β | Allowable blending angle |
| H | Holder |
| P | Pliers |
| F | Load measurement device |
| R | Measurement point |
| C_{A} | Bandwidth |
| D_{A} | Depth |
| K_{A} | Cutting edge |
| K_{B} | Cutting edge width |
| L_{A} | Length of cutting edge |
| L_{B} | Length of cutting edge |
| Lₜ | Free length (during testing) |
| S_{A} | Segment length or snap-off line intervals |
| S_{B} | Snapping line interval |
| T_{A} | Thickness |
| W_{A} | Whole width |
| W_{B} | Whole width |

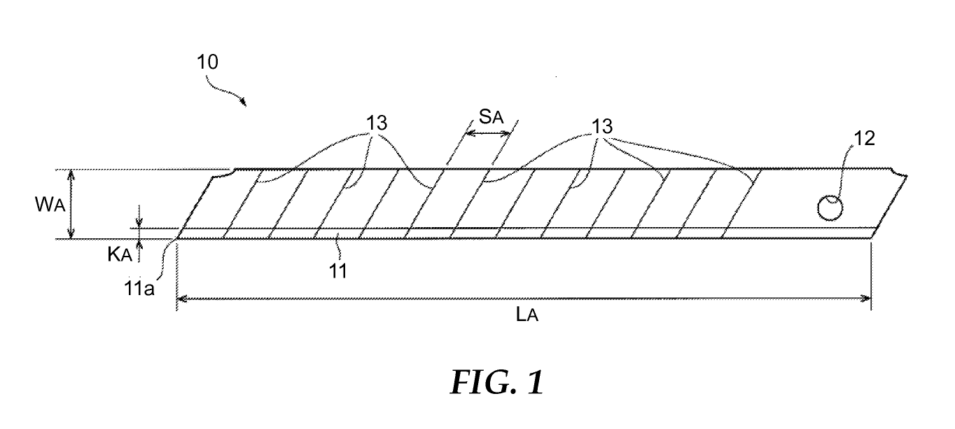

The illustrative cutter blade 10 shown in FIG. 1 is a replacement blade used for tools such as a cutter knife. The cutting edge 11 is formed along the longitudinal direction in a long cutter blade 10 at the intersection of the two major surfaces or sides of the blade. An end projected in the longitudinal direction to where the cutting edge 11 intersects the first end of the blade is point 11a of the cutter blade 10. In some embodiments, the blade will have two ends, optionally of substantially equal length; in some embodiments, the second end may be a point at which the first edge and second edge intersect one another.

An optional through-hole 12 for engaging with a tool (not shown) such as a hand held cutter knife is typically formed in the cutter blade 10.

The cutter blade 10 has one or more weakened lines of separation or blade snap-off lines 13 for snapping off the outermost segment as its cutting edge or point become worn out and chipped off due to usage. The blade snap-off line 13 is a linear groove in the blade body that is oriented at a predetermined angle to the cutting edge 11. Blades of the invention will preferably have two or more, and in some embodiments 12, 20 or more weakened lines of separation. In many embodiments, the lines of separation are arranged in parallel to one another. In many embodiments, the lines of separation are spaced apart at equal distances or equal longitudinal intervals to define equally sized segments of the blade.

Blades of the invention are made from metal cores as are conventionally used today. Those skilled in the art will be able to readily select suitable metals from which to make blades of the invention. Illustrative metals suitable for use herein include steel, e.g., stainless steel, carbon tool steel, alloy tool steel, etc. which are available in various formulations containing such additives as carbon, chromium, etc. to impart desired properties.

For example, commercially available carbon tool steel varieties suitable for use in blades of the invention include but are not limited to SK120 (C120U), SK140, SK105 (C105U), SK95, SK90 (C90U), SK85, SK80 (C80U), SK75, SK70 (C70U), SK65, and SK60, and commercially available alloy tool steel varieties suitable for use in blades of the invention include but are not limited to SKS11, SKS2, SKS2M, SKS21, SKS5, SKS51, SKS51M, SKS7M, etc.

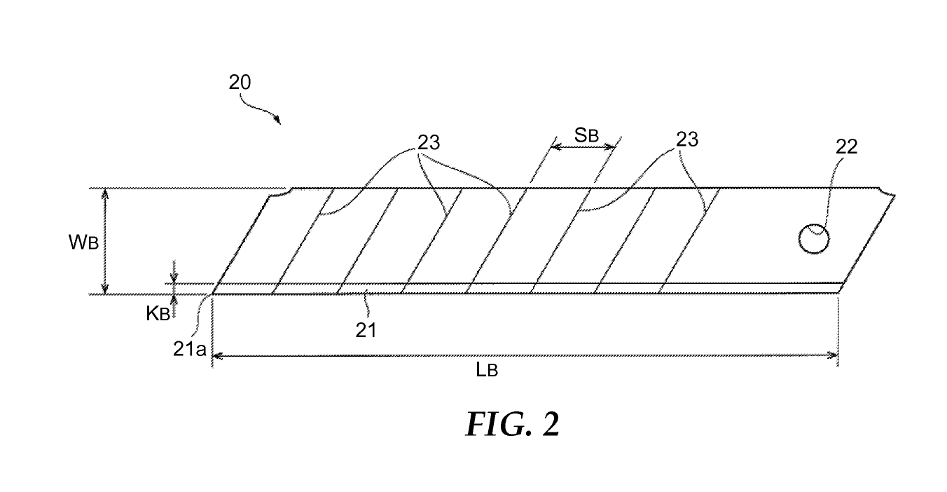

The number of segments and corresponding number of weakened separation lines or snap-lines as well as dimensions of the cutter blade 10 are not limited in particular and will be determined in large part based upon such factors as the sizes of materials and equipment available to make blades of the invention as well as desired applications. For example, as the dimension of a small size cutter blade 10, an overall length of about 84 to about 86 mm, the length L_{A} of the cutting edge 11 of about 79 to about 81 mm and the width W_{A} of about 0.85 to about 1.15 mm are illustrated, and the intervals S_{A} of the blade snap-off lines 13 are from about 4.98 to about 5.02 mm, the length of about 0.397 to about 0.403 mm, and the overall width of about 8 to about 10 mm are illustrated. In addition, as the dimension of a large size cutter blade 20 shown in FIG. 2, an overall length of about 109 to about 111 mm, the length L_{B} of the cutting edge 21 of about 99 to about 101 mm and the width K_{B} of about 1.35 to about 1.65 mm are illustrated, and the intervals S_{B} of the blade snap-off line 23 of about 9.98 to about 10.02 mm, the width T_{B} of about 0.498 to about 0.502 mm, and the overall width of about 17.5 to about 18.5 mm are illustrated.

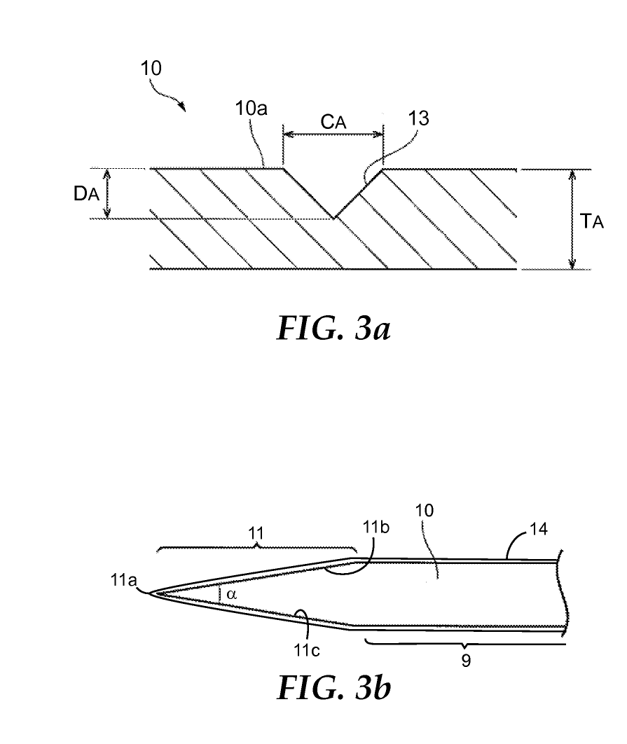

Next, the blade snap-off lines 13 and the cutting edge angle α of the cutter blade 10 is described with reference to FIGS. 3(a) and 3(b). FIG. 3(a) is a cross-sectional view of the cutter blade 10 illustrating the depth D_{A} of a blade snap-off line 13. In many embodiments, it will be preferred that each of the snap-off lines have similar depth and length.

The blade snap-off line 13 shown in FIG. 3(a) is formed such that the ratio of the depth D_{A} of the blade snap-off line 13 to the thickness T_{A} of the cutter blade 10 (i.e., the dimension from the first major surface to the second major surface thereof) is chosen to provide desired snap-off characteristics. In many embodiments, it is preferred that the force required to snap-off a segment of the cutter blade is from about 8N to about 25N.

If the depth of the snap-off line is insufficient, (in other words, the depth D_{A} is shallow), the blade will not easily snap off along the blade snap-off line 13, will lack flexibility, and the blade will tend to break off at a place other than the blade snap-off line 13. Further, if the relative depth of the snap-off line is too great, the resultant cutter blade may not exhibit sufficient strength for typical use, tending to break unexpectedly posing attendant safety and performance deficiencies. For instance, in embodiments where the thickness T_{A} of the cutter blade 10 is about 0.4 mm, the blade snap-off line is preferably formed such that its depth D_{A} from about 0.04 mm to about 0.24 mm, i.e., it has a ratio of about 0.1 to about 0.6 to the thickness of the cutter blade.

In addition, the blade snap-off line 13 is typically preferably formed such that the ratio of the depth D_{A} and the opening width C_{A} is from about 0.5 to about 2. Specifically, when the depth D_{A} is about 0.06 mm, the blade snap-off line 13 is formed such that the width C_{A} may be set to greater than about 0.03 mm but less than about 0.12 mm. The ratio of the depth D_{A} and a opening width C_{A} can be more than about 0.8 but less than about 1.2. The cross-sectional shape of the blade snap-off line 13 may be a triangle which sets the bottom of the blade snap-off line 13 as a vertex, and may be a rectangle, a semicircle, a semi-ellipse and the other shapes, but more specifically, the cross-sectional shape of the blade snap-off line 13 is typically in the form of an approximately equilateral triangle.

Note that, the thickness T_{A} of the cutter blade 10 is the thickness of the cutter blade after cutting. In addition, the depth D_{A} of the blade snap-off line 13 is an average depth from the surface 10a of the cutter blade 10 to the bottom of the blade snap-off line 13. The opening width C_{A} of the blade snap-off line is an average length of the width at major surface 10a of the cutter blade 10. The power required for the blade snap-off described later in detail is based on balance such as the hardness of the cutter blade 10, the thickness T_{A} of the cutter blade 10, the depth D_{A} of the blade snap-off line 13, and the thickness of the surface modification coating. The strength required to snap-off the blade may be selected as desired, and is typically from about 8N to about 25N, and in some instances is from about 10N to about 20N. If the strength required to snap off the blade is about 8N or more, there is a less chance for the cutter blade 10 to snap off unintentionally when being used, and if the strength required to snap-off the blade is about 10N or more, there are even less chance of being snapped off.

A characteristic of snap cutting blades is the allowable bending angle, i.e., the angle to which the blade may be bent without separating at the weakened line of separation. Measurement of the allowable bending angle of select embodiments of the invention is described in detail below, and is based in part upon as the hardness of the cutter blade 10, the thickness T_{A} of the cutter blade 10, the depth D_{A} of snap-off line 13, and the thickness of the surface modification coating. The allowable bending angle may be adjusted to about 45° or more, but may be adjusted to about 50° or more. In addition, the allowable bending angle may be adjusted to about 80° or less, and may be adjusted to about 75° or less.

FIG. 3(b) is a drawing of the cutter blade 10 seen from a longitudinal direction wherein is shown cutting tip 11a and edge enhancement coating 14. Conventionally, the cutting 11 will be formed by grinding an edge of a core from one or more both sides (both 11b, 11c in this embodiment) to form a sharpened cutting tip 11a. In many embodiments, the grinding to form edge 11 with flat surface sides, however, relatively concave, convex, or other profiles may be used if desired. As shown in FIG. 3(b), edge enhancement coating 14 covers both sides 11b, 11c of cutting tip 11a and extends beyond cutting edge 11 to substantially cover both major surfaces of body portion 9 of blade 10.

The cutter blade 10 shown in FIG. 3(b) is formed such that the included angle α of the cutting edge 11 is from about 10° to about 25°. If the cutting edge angle α of the cutting edge 11 is too low, the resultant cutting tip will not exhibit sufficient durability and effectiveness. In addition, if the included angle α is too large, the resultant blade will be deemed too dull. Selection of desired included cutting edge angle α will typically be from about 10° to about 25°, in some embodiments from about 15° to about 20°, and in some embodiments about 18°.

A blade core for fabrication of a snap cutter blade of the invention can be manufactured by conventionally known methods. That is, the blade core has: (1) an elongate body having two major surfaces connected by a first edge and a second edges and a first end and a second end, the first and second edges each extending from the first end to the second end; (2) at least one edge of the blade core is a cutting edge having a cutting tip having two sides, a first side corresponding to the first major surface of the blade core and a second side corresponding to the second major surface of the blade core; and (3) the blade core has one or more weakened lines of separation, the weakened lines of separation being parallel to one another and being located in longitudinal intervals, defining segments of the blade core;

For instance, a ribbon-shaped body of blade base material is formed to extend to at least the desired length, e.g., by rolling. Typically, a through-hole 12 and one or more blade snap-off lines 13 is formed by a press process. At this time, the groove for detaching the blade base material from a product unit is also formed. Then, the cutting edge 11 is formed on at least one side of the blade base material by polishing or grinding.

An edge enhancement coating, e.g., titanium nitride (TiN), is then applied to the blade core, at least to both sides of the cutting tip, and in some embodiments to substantially all of both major surfaces of the blade core.

An illustrative means of applying the edge enhancement coating is physical vapor deposition (“PVD”), e.g., such methods as vacuum deposition, cathode arc, or ion plating of hollow cathode, electron beam, ionized deposition, and sputtering forms of PVD.

In accordance with the invention, the edge enhancement coating is applied under conditions that will not undesirably degrade the core body. In many embodiments, the deposition will be carried out at a temperature of from about 40° C. up to about 400° C. or less. Applying the edge enhancement coating at such temperatures limits the heat softening undergone by the blade base or core material. Accordingly, the resultant cutter blade 10 will exhibit relatively higher hardness and excellent abrasion resistant can be obtained.

In typical embodiments, the Vickers hardness (Hv) of the resultant cutter blade 10 is at least about 240 or more. In some embodiments, the Vickers hardness (Hv) is preferably about 400 or more, more preferably about 500 or more, with increased hardness imparting increased durability.

Typically, application of the edge enhancement coating will be achieved in a deposition process lasting from about 1 to about 10 minutes, in some instances from about 4 to 5 minutes.

Another illustrative means of applying edge enhancement coatings in accordance with the invention includes chemical vapor deposition (“CVD”) e.g., plasma CVD and thermal CVD. In addition to titanium nitride (TiN), other illustrative examples of coatings that can be used in the present invention include zinc nitride (Zn₃N₂), titanium-carbon-nitride (TiCN), titanium aluminum nitride (TiAlN), titanium diboride (TiB₂), titanium carbide (TiC), zirconium boride (ZrB₂), zirconium carbide (ZrC), zirconium nitride (ZrN), vanadium boride (VB₂), vanadium carbide (VC), vanadium nitride (VN), niobium boride (NbB₂), niobium carbon (NbC), niobium nitride (NbN), tantalum diboride (TaB₂), tantalum carbide (TaC), chromium boride (CrB2), a trichromiumdicarbide (Cr₃C₂), chromium nitride (CrN), timolybdenumpentaboride (Mo₂B₅), molybdenum carbide (Mo₂C), ditungstenpentaboride (W₂B₅), tungsten carbide (WC), lanthanum boride (LaB₆), etc.

In addition, to PVD and CVD, edge enhancement coatings in accordance with the invention can be applied via wet plating, dipping, thermal spraying and coating. Note that, even in PVD, various methods such as a vacuum deposition, a cathode arc type, or an ion plating of hollow cathode type, an electron beam type, an ionized deposition, and a sputtering can be applied

The thickness of the edge enhancement coating is typically from about 0.1 μm to about 2.5 μm, sometimes preferably from about 0.12 μm to about 0.15 μm, and more preferably from about 1.5 μm to about 1 μm. If the thickness is less than about 0.1 μm, an adequate abrasion resistant is typically not obtained, and if the thickness exceeds to about 2.5 μm, the acuity of the cutting edge is typically lost as the edge enhancement coating yields a roughly concentric deposit on the cutting edge 11a, undesirably blunting the sharpness thereof. The measurement of the thickness of the surface modification coating is based on the CALOTEST® method using a CALOTEST® ball abrasion type precision film thickness measuring machine made by CSM Instruments SA.

Snap cutter blades of the invention exhibit a surprising combination of heretofore unattainted properties and performance. Blades of the invention exhibit superior higher abrasion resistance and corrosion resistance while still exhibiting effective snap-off performance.

Typically, cutter blades of the invention will be attached to a handle to form a tool for use.

### EXAMPLES

The present invention is described in more detail with the following illustrative examples.

### Examples S1 to S12

The small size cutter blade shown in FIG. 1 was used in Examples S1 to S12. The measurements of the cutter blade are such that the length of the cutting edge L_{A} is 80 mm, the width on the cutting edge K_{A} (dimension from cutting tip to body portion of blade) is 1.0 mm, the whole width W_{A} is 9.1 mm, the thickness T_{A} is 0.4 mm, and the interval S_{A} between the blade snap-off lines is 5 mm. The interior angle of the cutting tip was 18°. SK120 carbon tool steel was used as the blade base material, and titanium nitride was used as a coating material of a surface modification coating. Table 1 shows other fabrication conditions in Examples S1 to S12.

TABLE 1

| | Depth D_{A} | | Cutting Tip | | | |
|---|---|---|---|---|---|---|
| | of Blade | Ratio of | Interior | Cutting | Cutting | Cutting |
| | folding line | Depth D_{A} to | Angle α | Temperature | Time | Thickness |
| Example | (mm) | Thickness T_{A} | (°) | (° C.) | (min) | (μm) |
| S1 | 0.04 | 10% | 18 | 800 | 4 | 0.3 |
| S2 | 0.04 | 10% | 18 | 400 | 4 | 0.3 |
| S3 | 0.04 | 10% | 18 | 170 | 4 | 0.3 |
| S4 | 0.04 | 10% | 18 | 80 | 4 | 0.3 |
| S5 | 0.08 | 20% | 18 | 800 | 4 | 0.3 |
| S6 | 0.08 | 20% | 18 | 400 | 4 | 0.3 |
| S7 | 0.08 | 20% | 18 | 170 | 4 | 0.3 |
| S8 | 0.08 | 20% | 18 | 80 | 4 | 0.3 |
| S9 | 0.16 | 40% | 18 | 800 | 4 | 0.3 |
| S10 | 0.16 | 40% | 18 | 400 | 4 | 0.3 |
| S11 | 0.16 | 40% | 18 | 170 | 4 | 0.3 |
| S12 | 0.16 | 40% | 18 | 80 | 4 | 0.3 |
| Comparative S1 | 0.04 | 10% | 20 | — | — | 0.3 |
| Comparative S2 | 0.04 | 10% | 18 | — | — | 0.3 |

### Comparative Example S1

An oxide film was formed by the same SK120 on the surface, and the interior angle of the cutting tip was set to 20°. Other than the above, the remainder was similar to that of Example 1 as shown in Table 1.

### Comparative Example S2

The surface modification coating was not made using the same SK120 on the surface. Other than the above, the remainder was similar to that of Example 1 as shown in Table 1.

### Examples L1 to L26

The large cutter blade shown on FIG. 2 was used in the Examples L1 to S26. The measurements of the cutter blade are such that the length of the cutting edge L_{B} was 100 mm, the width on the cutting edge K_{B} was 1.5 mm, the whole width W_{B} was 17.8 mm, the thickness T_{B} was 0.5 mm, and the interval S_{B} between the blade snap-off lines was 10 mm. The interior degree of the cutting tip was to 18°. SK120 carbon tool steel was used as the blade base material, and titanium nitride was used as a coating material of a surface modification coating. Table 1 shows other fabrication conditions in Examples L1 to L26.

TABLE 2

| | Depth D_{A} | | Cutting Tip | | | |
|---|---|---|---|---|---|---|
| | of Blade | Ratio of | Interior | Cutting | Cutting | Cutting |
| | folding line | Depth D_{A} to | Angle α | Temperature | Time | Thickness |
| Example | (mm) | Thickness T_{B} | (°) | (° C.) | (min) | (μm) |
| L1 | 0.06 | 12% | 18 | 800 | 4 | 0.3 |
| L2 | 0.06 | 12% | 18 | 400 | 4 | 0.3 |
| L3 | 0.06 | 12% | 18 | 400 | 15 | 5 |
| L4 | 0.06 | 12% | 18 | 200 | 4 | 0.3 |
| L5 | 0.06 | 12% | 18 | 170 | 4 | 0.3 |
| L6 | 0.06 | 12% | 18 | 170 | 4 | 0.3 |
| L7 | 0.06 | 12% | 18 | 140 | 4 | 0.3 |
| L8 | 0.06 | 12% | 18 | 80 | 4 | 0.3 |
| L9 | 0.06 | 12% | 18 | 80 | 4 | 0.3 |
| L10 | 0.12 | 24% | 18 | 800 | 4 | 0.3 |
| L11 | 0.12 | 24% | 18 | 400 | 4 | 0.3 |
| L12 | 0.12 | 24% | 18 | 170 | 4 | 0.3 |
| L13 | 0.12 | 24% | 18 | 80 | 4 | 0.3 |
| L14 | 0.12 | 24% | 18 | 80 | 4 | 0.4 |
| L15 | 0.12 | 24% | 18 | 80 | 4 | 0.1 |
| L16 | 0.12 | 24% | 18 | 80 | 4 | 3 |
| L17 | 0.12 | 24% | 18 | 40 | 4 | 0.3 |
| L18 | 0.24 | 48% | 18 | 800 | 4 | 0.3 |
| L19 | 0.24 | 48% | 18 | 400 | 4 | 0.3 |
| L20 | 0.24 | 48% | 18 | 200 | 4 | 0.3 |
| L21 | 0.24 | 48% | 18 | 170 | 4 | 0.3 |
| L22 | 0.24 | 48% | 18 | 170 | 4 | 0.3 |
| L23 | 0.24 | 48% | 18 | 140 | 4 | 0.3 |
| L24 | 0.24 | 48% | 18 | 80 | 4 | 0.3 |
| L25 | 0.24 | 48% | 18 | 80 | 4 | 0.3 |
| L26 | 0.36 | 48% | 18 | 80 | 4 | 0.3 |
| Comparative L1 | 0.04 | 12% | 20 | — | — | — |
| Comparative L2 | 0.04 | 12% | 18 | — | — | — |

### Comparative Example L1

An oxide film was formed by the same SK120 on the surface, and the interior angle of the cutting tip was 20°. Other than the above, the remainder was similar to that of Example L1 as shown in Table 2.

### Comparative Example L2

The surface modification coating was not provided on the surface using the same SK120. Other than the above, the remainder was similar to that of Example L1 as shown in Table 2.

Vickers Hardness Test

Vickers hardness test (Hv) and the force required to snap off the cutting blade (N) was measured for Examples S1 to S12, L1, L2, L4 to L13, L17 to L26, and Comparative Examples S1, S2, L1, and L2. With regards to hardness, the hardness of the cutter blade before and after the coating were measured based on the JIS standard Z2244. Portable Hardness Tester DHT-100 (Sato Trading Co., Ltd.) was used as a hardness measurement device. The measurement result is shown in Table 3 and 4.

### Table 3

TABLE 3

| | Harness | Hardness | Blade | Allowable | | | | |
|---|---|---|---|---|---|---|---|---|
| | before | after | Folding | Bending | Blade | | Sharpness | Sharpness |
| | Cutting | Cutting | Power | Angle β | Folding | Blade Lacking | Test | Test |
| Example | (HV) | (HV) | (N) | (°) | Test | Characteristic | (ICP) | (Life Test) |
| S1 | 825 | 348 | 23.8 | 60 | A | A | — | — |
| S2 | 825 | 563 | 25.2 | 55 | A | A | — | — |
| S3 | 825 | 784 | 30.1 | 55 | A | A | — | — |
| S4 | 825 | 813 | 28.3 | 65 | A | A | — | — |
| S5 | 825 | 353 | 10.2 | 55 | A | A | — | — |
| S6 | 825 | 555 | 15.2 | 55 | A | A | — | — |
| S7 | 825 | 795 | 11.1 | 65 | A | A | — | — |
| S8 | 825 | 811 | 12.5 | 65 | A | A | — | — |
| S9 | 825 | 365 | 8.6 | 50 | A | A | — | — |
| S10 | 825 | 573 | 9.7 | 50 | A | A | — | — |
| S11 | 825 | 800 | 8.7 | 60 | A | A | — | — |
| S12 | 825 | 815 | 10.1 | 60 | A | A | — | — |
| Comparative S1 | — | 650 | 8.9 | 30 | B | B | — | — |
| | | (Oxide film) | | | | | | |
| Comparative S2 | 825 | No Coat | 10.7 | 30 | B | B | — | — |

### Table 4

TABLE 4

| | Hardness | Hardness | Blade | Allowable | | | | |
|---|---|---|---|---|---|---|---|---|
| | before | after | Folding | Bending | Blade | | Sharpness | Sharpness |
| | Cutting | Cutting | Power | Angle β | Folding | Blade Lacking | Test | Test |
| Example | (HV) | (HV) | (N) | (°) | Test | Characteristic | (ICP) | (Life Test) |
| L1 | 811 | 288 | 38.8 | 60 | A | A | — | — |
| L2 | 811 | 515 | 45.2 | 65 | A | A | — | — |
| L3 | — | — | 31.2 | — | A | B | — | — |
| L4 | 855.19 | 581.27 | 58.8 | 70 | A | A | — | — |
| L5 | 811 | 774 | 60.1 | 75 | A | A | — | — |
| L6 | 855.19 | 610.77 | 66.7 | 70 | A | A | — | — |
| L7 | 833.43 | 649.77 | 58.5 | 70 | A | A | — | — |
| L8 | 811 | 806 | 58.3 | 75 | A | A | — | — |
| L9 | 833.43 | 802.89 | 67.4 | 70 | A | A | — | — |
| L10 | 811 | 297 | 20.2 | 65 | A | A | — | — |
| L11 | 811 | 564 | 19.3 | 60 | A | A | — | — |
| L12 | 811 | 780 | 18.4 | 70 | A | A | — | — |
| L13 | 811 | 811 | 18.2 | 70 | A | A | 88.1 | 385 |
| L14 | — | — | 18.4 | — | A | A | — | — |
| L15 | — | — | 14.7 | — | A | A | — | — |
| L16 | — | — | 28.1 | — | A | B | — | — |
| L17 | 811 | 811 | 17.4 | 65 | A | A | — | — |
| L18 | 811 | 248 | 15.3 | 50 | A | A | — | — |
| L19 | 811 | 525 | 16.8 | 50 | A | A | — | — |
| L20 | 811.84 | 537.05 | 19.2 | 65 | A | A | — | — |
| L21 | 811 | 773 | 15.2 | 55 | A | A | — | — |
| L22 | 811.84 | 544.97 | 17.7 | 70 | A | A | — | — |
| L23 | 784.28 | 614.97 | 13.3 | 70 | A | A | — | — |
| L24 | 811 | 803 | 14.1 | 60 | A | A | — | — |
| L25 | 784.28 | 743.93 | 14.8 | 70 | A | A | — | — |
| L26 | 811 | 810 | 4.2 | 15 | A | A | — | — |
| Comparative L1 | — | 650 | 15.4 | 35 | B | B | 87.7 | 347.4 |
| | | (Oxide film) | | | | | | |
| Comparative L2 | 811 | No Coat | 18.4 | 35 | C | B | 89.9 | 355.6 |

Snap Off Test

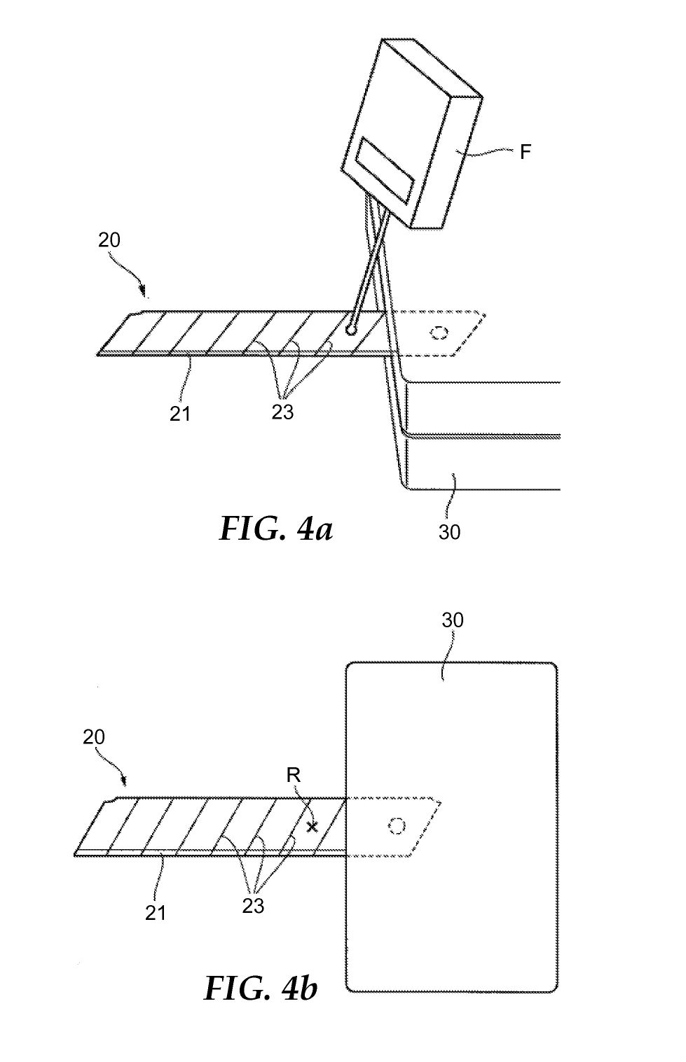

The force required to snap off a segment of the blade (Snap off force) (N) was measured for Examples S1 to S12 and L1 to L26, and Comparative Examples S1, S2, L1 and L2. The snap off test was carried out with the opposite end from the blade tip (base end of the blade) of the cutter blade 10, 20 held in the vice 30. More specifically, in the large cutter blade 20 shown in FIG. 4(b), when the region 30 mm from the tip of the original blade side (in other words, the cutting edge 21 of the cutter blade 20 and the back of the opposite side and the original blade side from the intersection of the blade snap-off line 23 of the most original blade side) was held by the vice 30, a load was added in a thickness direction to the measuring point R and was measured where the snapping off of the blade took place, such that the axis of the cutter blade 20 was perpendicular to the held portion of the vice 30. Furthermore, in the small size cutter blade 10, when the region 20 mm from the tip of the original blade side (in other words, the cutting edge 11 of the cutter blade 10 and the back of the opposite side and the original blade side from the intersection of the blade snap-off line 23 of the most original blade side) was held by the vice 30, a load was added perpendicular to the measuring point R and was measured where the snapping off of the blade took place, such that the ground line of the cutter blade was perpendicular to the clipped portion of the vice 30. The measuring point R is the midpoint of the second blade snap-off line and the first blade snap-off line from the original blade side in the longitudinal direction, and turns into a full midpoint in a crosswise direction of the cutter blade 10, 20. In addition, an RX-1 (Aikoh Engineering Co., Ltd.) was used as a load measurement device. The measurement result is shown in Table 3 and 4.

Flexibility Test

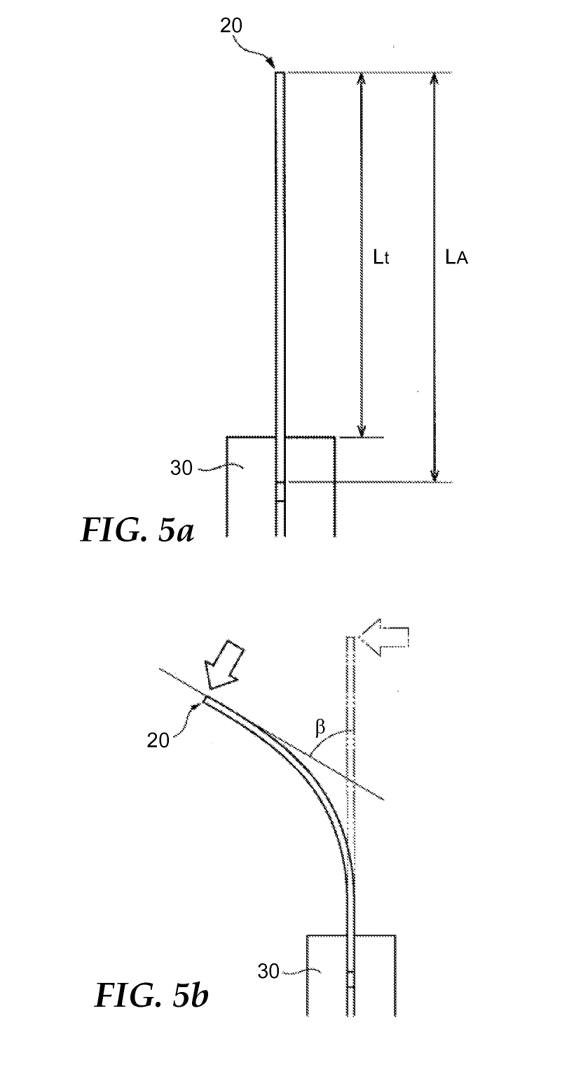

The flexibility was measured for Examples S1 to S12, L1 to L13, L17 to L26, and Comparative Examples S1, S2, L1, L2. As shown in FIG. 5(a), flexibility test (acceptable angle bending test) is performed with the opposite end of the cutting edge of the cutter blades 10 and 20 clamped in the vise 30. More specifically, the base is clamped with a vise from the point that the snap-off lines 13 and 23 and the edges 11 and 21 by the former side of crossed heel such that the axis line of the cutter blades 10 and 20 is perpendicular to the clamped portion of the vise. In other words, in the small size cutter blade 10, the ratio of the free length Lₜ to the length L_{A} of the edge 11 which are not clamped is about 0.25. Specifically, the length Lₜ is set to about 20 mm in the case where the length L_{A} of the edge 11 is 80 mm. In addition, in the large size cutter blade 20, the ratio of the length Lₜ and the length L_{B} of the edge 21 which are not clamped is about 0.3. Specifically, the length Lₜ is set to about 30 mm in the case where the length L_{B} of the edge 11 is 100 mm.

FIG. 5(b) describes the allowable bending angle β of the cutter blades 10 and 20. As shown in FIG. 5(b), in the flexibility test, allowable bending angle β is measured by applying force in the thickness direction to the points 11a and 21a of the cutter blades 10 and 20. The allowable bending angle β is an angle between the perpendicular and tangent side of the point just before the bending form of the cutter blades 10 and 20 in the thickness direction which can cause snapping-off.

As the result of the flexibility test shown on Table 3 and 4, the Examples S1 to S12, L1, L2, L4 to L13, L17 to L25, have an allowable bending angle β of 50° to 70°. Meanwhile, the Comparative Examples S1, S2, L1 and L2 have an allowable bending angle of 30° to 35°. In Examples S1 to S12, L1 to L25, a large improvement flexibility is confirmed.

Blade Snap-off Test

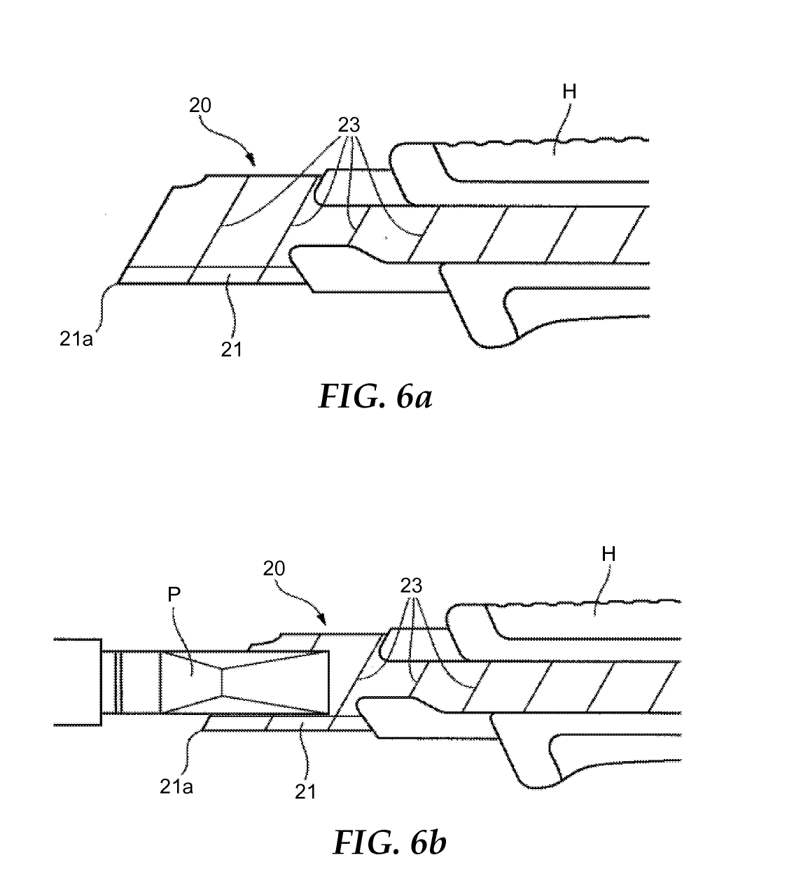

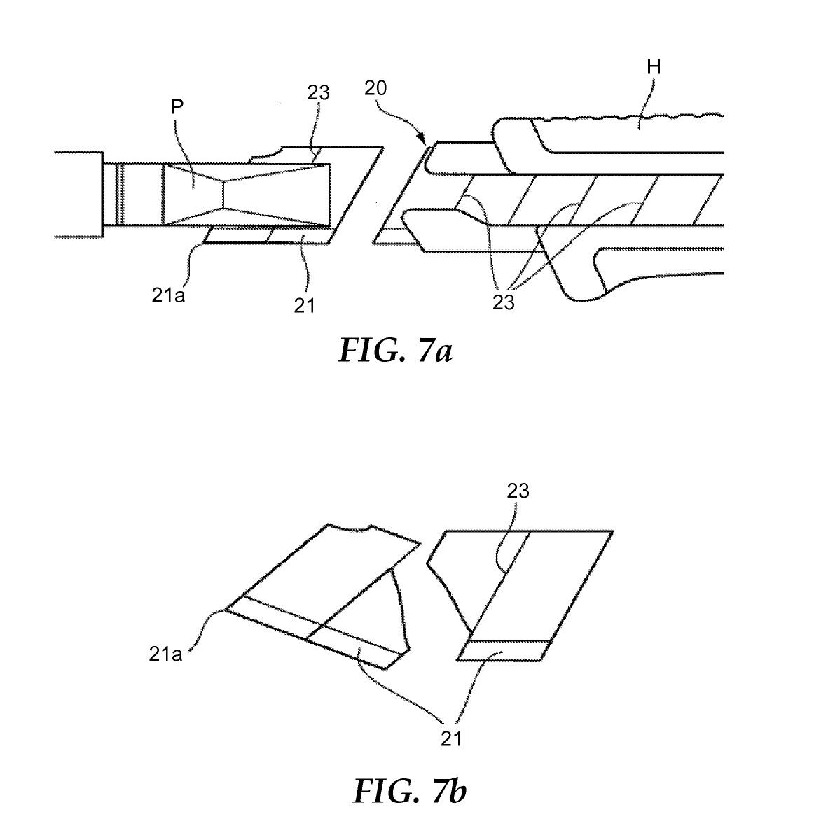

A blade snap-off test of a cutter blade is described with reference to FIGS. 6 and 7 with regards to Examples S1 to S12, L1 to L26, and Comparative Examples S1, S2, L1 and L2. In addition, the large size cutter blade 20 is illustrated in FIG. 6 and FIG. 7.

After properly attaching the cutter blades 10 and 20 to the holder H which suits the size of the cutter blades 10 and 20, the blade snap-off test is done, where the cutter blade 10 is extended so that the two blade snap-off lines 13 and 23 are exposed from the tip (refer to FIG. 6). The cutter blades 10 and 20 are held with pliers P to stride over the first blade snap-off line 13 and 23 from the side of point 11a and 21a of the exposed cutter blade 10 and 20 from the holder tip (refer to FIG. 6(b)), and snap-off the cutter blade 10 and 20 by applying a bending load in the thickness direction of the cutter blade 10 and 20.

The blade snap-off is performed 5 times for the large size and 3 times for the small size per one cutter blade 10 and 20, and such operation is repeated 3 times per each size, in other words, the operation took place 15 times for the large size and 9 times for the small size. In such blade snap-off work, the blade that was snapped off in all pieces (refer to FIG. 7(a)) by the second blade snap-off line 13 and 23 from the point 11a and 21a was set to A, the blade that was snapped off once at a place other than the blade snap-off line 13 and 23 was set to B, and the blade that was snapped off twice was set to C.

As a result on the blade snap off test shown in Tables 3 and 4, Examples S1 to S12, L1 to L26 having a surface modification coating applied to the whole surface all had A rating on the evaluation. Meanwhile, the Comparative Examples S1, S2, L1 and L2 which had an oxide layer or were not provided with a surface modification coating was rated B or C on the evaluation. In Examples S1 to S12, L1 to L26 which had a surface modification coating applied to the whole surface, all the blades snapped off at the right place.

Chipping Blade Test

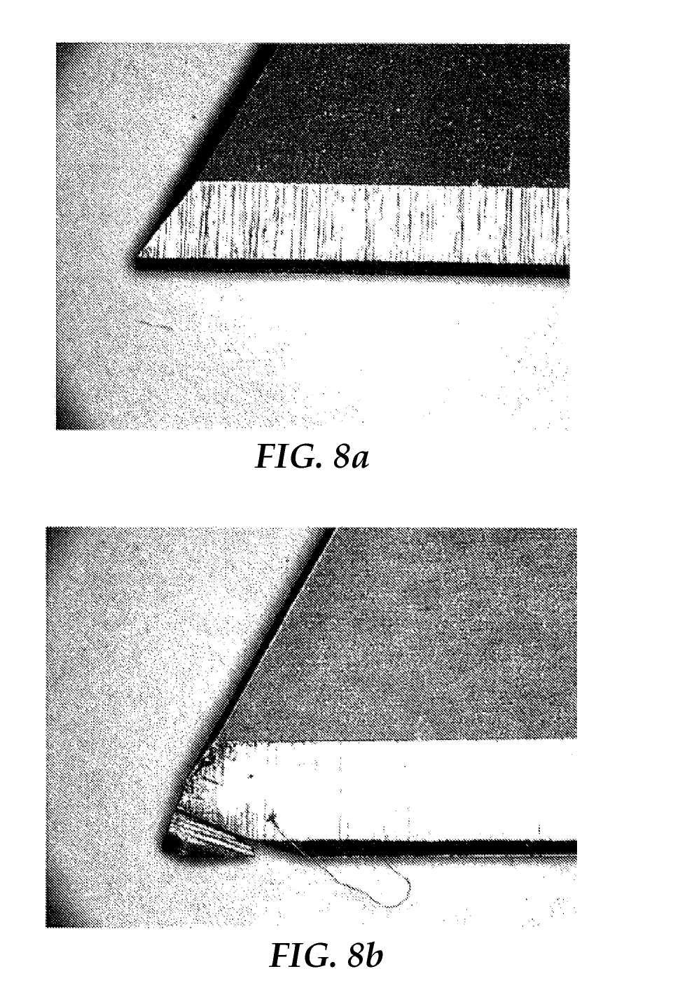

Next, the chipping blade test of the cutter blade will be described based on Examples S1 to S12, L1 to L26, and Comparative Examples S1, S2, L1 and L2. In the chipping blade test, an optical microscope was used to observe the shape of the tips 11a and 21a after 20 200-mm cuts were made to copy paper (A4 size) placed on a cutting mat, and those tips with changes in the shape before and after the test were set to A (refer to FIG. 8(a) for those tips with no changes in the shape and was set to B (refer to FIG. 8(b)).

As a result of the chipping blade test shown in Tables 3 and 4, the Examples L3 and L16 is more than 3 μm of the Examples S1 to S12, L1 to L26 having a surface modification coating applied to the whole surface which had B rating, all became A rating in the evaluation. Meanwhile, the Comparative Examples S1, S2, L1, and L2, which had an oxide layer or were not given a surface modification coating, all had B rating in the evaluation. The blade does not chip easily irrespective of the hardness of the cutter blade except in the case where the coating thickness of surface modification coating is more than 3 μm.

Sharpness Test

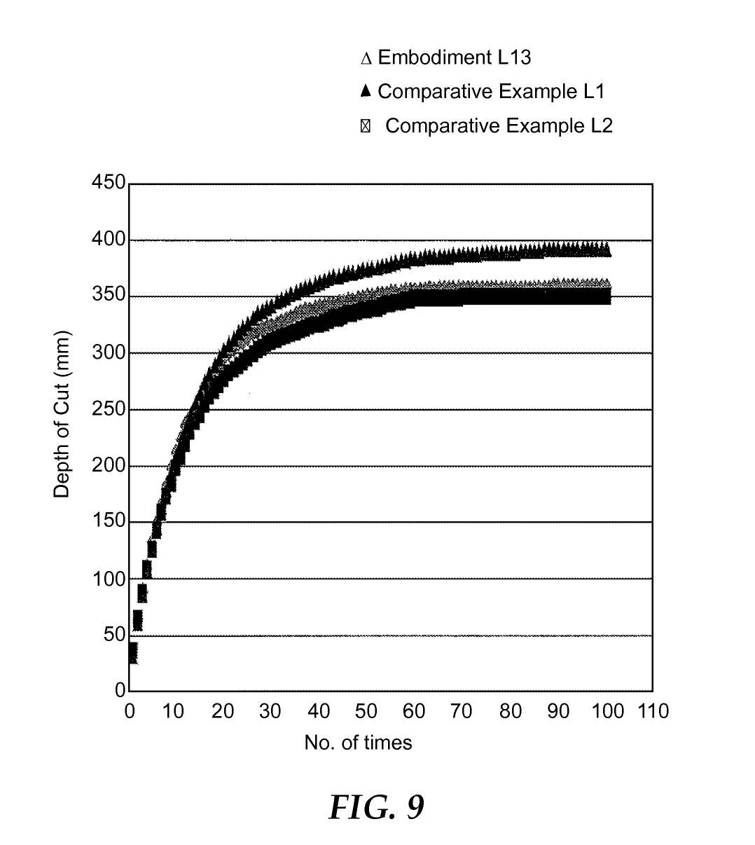

Further, the cutter blade sharpness test will be described based on Examples L13 and Comparative Examples L1 and L2. The sharpness test was carried out in accordance with the procedure prescribed in ISO-8442-5. More specifically, the cutter blades 10 and 20 were set perpendicularly, the blade was placed on top the stack of prescribed paper and the paper was moved back and forth when the paper was in contact with the blade, and the depth of the cut for each stroke was measured. The sharpness and durability of an edge from the test result are calculated through the value of Life Test which indicates the durability and ICP (Sharpness Test). Calculated ICP and Life Test value are shown in Table 4. Furthermore, the test result of the cut depth obtained from Life Test and the number of times of a cut is shown in FIG. 9. The vertical axis of FIG. 9 shows the cut depth (mm), and the horizontal axis shows the number of times of the cut.

As shown in Table 4, while Example L13 is the same ICP (Sharpness Test) as Comparison Examples L1 and L2, it has a large Life Test value and superior in flexibility. Further, as shown in FIG. 9, even if the number of times of the cuts increased for Example L13, a deep cut depth was able to be achieved in comparison with Comparison Example L1 and L2.

From the various test described above, a cutter blade was obtained that can be snapped off at an appropriate place along the snap-off line at an appropriate place without approaching a high degree of hardness for the cutter blade, has flexibility of the whole blade, and displays good chipping characteristics and snap-off characteristics by giving a surface modification coating to the entire surface of the snap-off type cutter blade having the blade snap-off line, and providing a blade snap-off line of appropriate depth. Further, cutter blade was obtained that not only has good flexibility, chipping characteristics, and snap-off characteristics, also has good durability by achieving a balance between the hardness of the blade base material, the coating thickness of the surface modification coating, and the depth of the blade snap-off line.

1. A snap cutter blade comprising a core and an enhancement coating thereon wherein:
(a) the blade is an elongate body having two major surfaces connected by a first edge and a second edge and a first end and a second end, the first and second edges each extending from the first end to the second end;
(b) at least one edge of the blade is a cutting edge having a cutting tip having two sides, a first side corresponding to the first major surface of the blade and a second side corresponding to the second major surface of the blade; and
(c) the blade has one or more weakened lines of separation, the weakened lines of separation being parallel to one another and being located in longitudinal intervals, defining separable segments of the blade, each weakened line of separation having a depth D_{A} and opening width C_{A} wherein the ratio D_{A}:C_{A} is from 0.5:1 to 2:1;
wherein the enhancement coating at least covers both the first side and the second side of the cutting tip.

2. The blade of claim 1 wherein the ratio of the depth of the weakened line of separation to the cutter blade thickness is from about 0.10:1 to about 0.60:1.

3. (canceled)

4. (canceled)

5. The blade of claim 1 wherein the force required to snap-off a segment of the cutter blade is from about 8N to about 25N.

6. The blade of claim 1 wherein the Vickers hardness (Hv) of the cutter blade is at least about 240 or greater.

7. The blade claim 1 wherein the coating materials of the surface modification coating is one selected from among either titanium nitride, nitriding zinc, carbonization titanium nitride, or titanium aluminum nitride.

8. The blade according of claim 1 wherein the included angle of the cutting tip is from about 10° to about 25°.

9. The blade of claim 1 wherein the average thickness of the enhancement coating is from about 0.1 μm to about 2.5 μm.

10. (canceled)

11. The blade of claim 1 wherein the second edge is a cutting edge having a cutting tip having two sides, a first side corresponding to the first major surface of the blade and a second side corresponding to the second major surface of the blade.

12-16. (canceled)

17. A tool comprising a snap cutter blade of claim 1.

18. A method for making a snap cutter blade comprising:
(a) providing a blade core wherein:
(1) the blade core is an elongate body having two major surfaces connected by a first edge and a second edges and a first end and a second end, the first and second edges each extending from the first end to the second end;
(2) at least one edge of the blade core is a cutting edge having a cutting tip having two sides, a first side corresponding to the first major surface of the blade core and a second side corresponding to the second major surface of the blade core; and
(3) the blade core has one or more weakened lines of separation, the weakened lines of separation being parallel to one another and being located in longitudinal intervals, defining segments of the blade core, each weakened line of separation having a depth D_{A} and opening width C_{A} wherein the ratio D_{A}:C_{A} is from 0.5:1 to 2:1; and
(b) forming an edge enhancement coating thereon by applying a coating composition to both sides of the cutting tip,
to yield a snap cutter blade.

19. The method of claim 18 wherein the ratio of the depth of the weakened line of separation to the blade core thickness is from about 0.10:1 to about 0.60:1.

20. The method of claim 18 where the Vickers hardness (Hv) of the resultant snap cutter blade is at least about 240 or more.

21. The method of claim 18 wherein the edge enhancement coating covers substantially all of both major surfaces of the blade.
